(19) United States
(12) Patent Application Publication
(10) Pub. No.: US 2025/0203001 A1
(43) Pub. Date: Jun. 19, 2025

(54) OPTICAL MODULE CAGE INCLUDING METAL PAD

(71) Applicants: Samsung Electronics Co., Ltd., Suwon-si (KR); MS ELECTRONICS CO., LTD., Seongnam-si (KR)

(72) Inventors: Sangyub KIM, Suwon-si (KR); Yongjoo KIM, Seongnam-si (KR); Hansang KIM, Suwon-si (KR); Sangbong YU, Suwon-si (KR)

(21) Appl. No.: 19/066,886

(22) Filed: Feb. 28, 2025

Related U.S. Application Data
(63) Continuation of application No. PCT/KR2023/012169, filed on Aug. 17, 2023.

(30) Foreign Application Priority Data
Aug. 30, 2022 (KR) 10-2022-0109520

(51) Int. Cl. H04M 1/02; H05K 7/20

(52) U.S. Cl. CPC H04M 1/0264; H04M 1/0274; H04M 1/0277; H05K 7/205

(57) ABSTRACT

An optic cage is provided. The optic cage includes a first cage for accommodating an optical module, a second cage for supporting the optical module, and a metal pad, wherein a side of the metal pad is coupled to a side of the optical module, wherein a plurality of grooves is formed on the side of the metal pad, wherein an opening is formed on the side of the first cage, wherein a plurality of plate spring structures integrally formed with the first cage is disposed within the opening, wherein the plurality of plate spring structures is respectively coupled to a corresponding groove among the plurality of grooves, and wherein the metal pad is movably disposed by insertion of the optical module into the first cage or withdrawal of the optical module from the first cage.

### CROSS-REFERENCE TO RELATED APPLICATION(S)

This application is a continuation application, claiming priority under 35 U.S.C. § 365(c), of an International application No. PCT/KR2023/012169, filed on Aug. 17, 2023, which is based on and claims the benefit of a Korean patent application number 10-2022-0109520, filed on Aug. 30, 2022, in the Korean Intellectual Property Office, the disclosure of which is incorporated by reference herein in its entirety.

### JOINT RESEARCH AGREEMENT

The disclosure was made by or on behalf of the below listed parties to a joint research agreement. The joint research agreement was in effect on or before the date the disclosure was made and the disclosure was made as a result of activities undertaken within the scope of the joint research agreement. The parties to the joint research agreement are 1) SAMSUNG ELECTRONICS CO., LTD. and 2) MS ELECTRONICS CO., LTD.

### BACKGROUND

### 1. Field

The disclosure relates to an optical module cage including a metal pad.

### 2. Description of Related Art

An optical module that converts an optical signal into an electrical signal or an electrical signal into an optical signal may be used for communication. To secure an optical module within a communication equipment, a cage for accommodating the optical module may be disposed on a substrate. A connector for electrical connection to the substrate may be coupled to the cage of the optical module. The optical module may perform optical communication, based on optical signals transmitted or received to/from an optical fiber and electrical signals transmitted or received to/from a substrate.

The above information is presented as background information only to assist with understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an optical module cage including a metal pad.

Additional aspects will be set forth in part in the description which follows and, in part, will be apparent from the description, or may be learned by practice of the presented embodiments.

In accordance with an aspect of the disclosure, an optical cage is provided. The optical cage includes a first cage for accommodating an optical module, a second cage for supporting the optical module, and a metal pad, wherein a side of the metal pad is coupled to a side of the optical module, wherein a plurality of grooves is formed on the side of the metal pad, wherein an opening is formed on the side of the first cage, wherein a plurality of plate spring structures integrally formed with the first cage is disposed within the opening, wherein the plurality of plate spring structures is coupled to a corresponding groove among the plurality of grooves, wherein the metal pad is movably disposed by insertion of the optical module into the first cage or withdrawal of the optical module from the first cage.

In accordance with an aspect of the disclosure, a communication equipment is provided. The communication equipment includes a heat dissipation fin, a thermal interface material (TIM), an optical module, an optical cage, and a printed circuit board (PCB), wherein the optical cage is disposed on a side of the PCB, wherein the optical cage includes a first cage for accommodating an optical module, a second cage for supporting the optical module, and a metal pad, wherein a side of the metal pad is coupled to a side of the optical module, wherein a plurality of grooves is formed on the side of the metal pad, wherein an opening is formed on a side of the first cage, wherein a plurality of plate spring structures integrally formed with the first cage is disposed within the opening, wherein the plurality of plate spring structures is coupled to a corresponding groove among the plurality of grooves, and wherein the metal pad is movably disposed by insertion of the optical module into the first cage or withdrawal of the optical module from the first cage.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A illustrates a wireless communication system according to an embodiment of the disclosure;

FIG. 1B illustrates communication equipment including a cage and an optical module according to an embodiment of the disclosure;

FIG. 2 illustrates enclosure-type cages according to an embodiment of the disclosure;

FIG. 3A illustrates a metal pad-type cage according to an embodiment of the disclosure;

FIG. 3B is an exploded perspective view of a metal pad-type cage according to an embodiment of the disclosure;

FIGS. 4A and 4B illustrate performance of a metal pad-type cage according to various embodiments of the disclosure;

FIGS. 5A and 5B illustrate placement of an optical module and a heat dissipation component according to various embodiments of the disclosure;

FIG. 6 illustrates a contact structure of a metal pad-type cage according to an embodiment of the disclosure;

FIG. 7 illustrates a coupling part of a metal pad-type cage according to an embodiment of the disclosure; and

FIGS. 8A and 8B illustrate a stacked structure of a metal pad-type cage according to various embodiments of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

The terms used herein, including technical and scientific terms, may have the same meanings as those commonly understood by those skilled in the art to which the disclosure pertains. Terms defined in a general dictionary among the terms used in the disclosure may be interpreted as having the same or similar meaning as those in the context of the related art, and they are not to be construed in an ideal or overly formal sense, unless explicitly defined in the disclosure. In some cases, even the terms defined in the disclosure may not be interpreted to exclude embodiments of the disclosure.

In various examples of the disclosure described below, a hardware approach will be described as an example. However, since various embodiments of the disclosure may include a technology that utilizes both the hardware-based approach and the software-based approach, the various embodiments are not intended to exclude the software-based approach.

As used in the following description, terms referring to signals (e.g., signal, information, message, signaling), terms for operational states (e.g., step, operation, procedure), terms referring to data (e.g., packet, user stream, information, bit, symbol, codeword), terms referring to channels, terms referring to network entities, terms referring to components of a device and so on are provided as examples for convenience of explanation. Accordingly, the disclosure is not limited to the terms described below, and other terms having the equivalent technical meaning thereto may be interchangeably used.

As used herein, terms referring to parts of an electronic device (e.g., substrate, print circuit board (PCB), flexible PCB (FPCB), module, antenna, antenna element, circuit, processor, chip, component, device), terms referring to the shape of parts (e.g., structure, enclosure, groove, pad, support, contact, protrusion), terms referring to the characteristics of a structure (e.g., leaf spring, coupling, connector), terms referring to connection between structures (e.g., connection, contact, support, contact structure, conductive member, assembly), terms referring to circuitry (e.g., PCB, FPCB, signal line, feeding line, data line)), radio frequency (RF) signal line, antenna line, RF path, RF module, RF circuit, splitter, divider, coupler, combiner), and so on are exemplified for convenience of explanation. Accordingly, the disclosure is not limited to the terms described below, and other terms having the equivalent technical meaning thereto may be interchangeably used. Further, as used herein, the terms, such as e.g., ‘˜portion’, ‘˜part’, ‘˜unit’, ‘˜module’, ‘˜body’, or the like may refer to at least one shape of structure or a unit for processing a certain function.

Further, throughout the disclosure, an expression, such as e.g., ‘above (more than)’ or ‘below (less than)’ may be used to determine whether a specific condition is satisfied or fulfilled, but it is merely of a description for expressing an example and is not intended to exclude the meaning of ‘more than or equal to’ or ‘less than or equal to’. A condition described as ‘more than or equal to’ may be replaced with an expression, such as ‘above’, a condition described as ‘less than or equal to’ may be replaced with an expression, such as ‘below’, and a condition described as ‘more than or equal to and below’ may be replaced with ‘above and less than or equal to’, respectively. Further, hereinafter, ‘A’ to ‘B’ means at least one of the elements from A (including A) to B (including B). Hereinafter, ‘C’ and/or ‘D’ means including at least one of ‘C’ or ‘D’, that is, {‘C’, ‘D’, or ‘C’ and ‘D’}.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

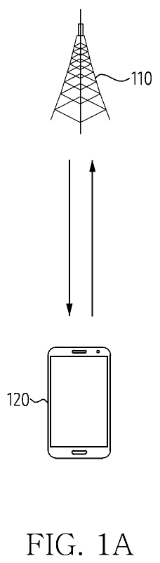

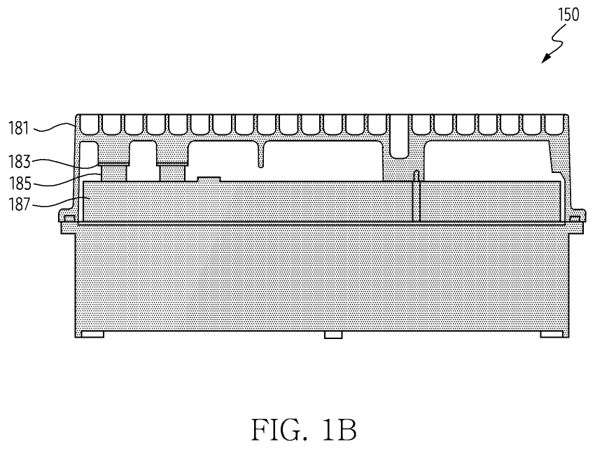

FIG. 1A illustrates a wireless communication system according to an embodiment of the disclosure.

Referring to FIG. 1A, illustrated are a base station 110 and a terminal 120 as some of nodes that use a wireless channel in a wireless communication system. Although FIG. 1A illustrates only one base station, the wireless communication system may further include another base station that are the same as or similar to the base station 110.

The base station 110 is a network infrastructure that provides wireless access to the terminal 120. The base station 110 has a coverage defined based on a distance at which signals can be transmitted. In addition to the term ‘base station’, the base station 110 may be referred to as ‘access point (AP)’, ‘eNodeB (eNB)’, ‘5^{th} generation node (5G node)’, ‘next generation nodeB (gNB)’, ‘wireless point’, ‘transmission/reception point (TRP)’, or other terms with the equivalent technical meaning thereto.

The terminal 120 is a device used by a user to communicate with the base station 110 over a wireless channel. A link from the base station 110 to the terminal 120 is referred to as downlink (DL), and a link from the terminal 120 to the base station 110 is referred to as uplink (UL). Further, although not illustrated in FIG. 1A, the terminal 120 and another terminal may communicate with each other through a wireless channel. In this context, the link between the terminal 120 and another terminals device-to-device link (D2D) is referred to as a sidelink, and the sidelink may be used interchangeably with a PC5 interface. In some other embodiments of the disclosure, the terminal 120 may operate without user involvement. According to an embodiment of the disclosure, the terminal 120 is a device that performs machine type communication (MTC) and may not be carried by a user. Further, according to an embodiment of the disclosure, the terminal 120 may be a narrowband (NB)-Internet of things (IoT) device.

The terminal 120 may be referred to, in addition to the terminal, as ‘user equipment (UE)’, ‘customer premises equipment (CPE)’, ‘mobile station’, ‘subscriber station’, ‘remote terminal’, ‘wireless terminal’, ‘electronic device’, or a ‘user device’ or other terms with equivalent technical meaning thereto.

Conventionally, in a communication system in which the base station has a relatively large cell radius, each base station has been installed to have functions of a digital processing unit (or distributed unit (DU)) and a radio frequency (RF) processing unit (RF processing unit, or RU). However, as higher frequency bands are used in 4^{th} generation (4G) and/or its subsequent communication systems (e.g., 5G) and the cell coverage of base stations becomes smaller, the number of base stations to cover a specific area has increased. Further, the burden for installation costs on the operators to install base stations has also increased. In order to minimize the installation costs of the base station, a structure has been proposed in which the DU and RU of the base station are separated so that one or more RUs are connected to one DU via a wired network, and one or more RUs are deployed geographically distributed to cover a specific area.

The communication equipment, such as a RU, massive multiple input multiple output (MIMO) unit (MMU), or access unit (AU) for connection to the DU may be provided with an optical module for optical communications. Hereinafter, the disclosure relates to a structure for improving heat dissipation characteristics of a cage in which such an optical module is mounted and communication equipment including the structure. More specifically, the disclosure describes a technology to improve the heat dissipation performance by reducing an air gap between the optical module and the cage and increasing its contact surface through a metal pad coupled to one side of the cage on which the optical module is mounted.

FIG. 1B illustrates a communication equipment including a cage and an optical module according to an embodiment of the disclosure.

Referring to FIG. 1B, a communication equipment 150 may be a component of the base station 110 of FIG. 1A. For example, communication equipment may include a RU. For example, the communications equipment may include an MMU for 5G networks. For example, the communication equipment may include an AU, which is in an integrated form of DU and RU.

Referring to FIG. 1B, the communication equipment 150 may include a heatsink (body heatsink) 181. The heatsink 181 may be formed as a main body of the communication equipment 150. The heatsink 181 has a material and structure specialized for conduction and radiation of heat, taking heat away from a heat-generating system and dissipating the heat to the surroundings. The heatsink 181 may radiate the heat transferred from its interior (e.g., a thermal interface material (TIM) 183) into the surrounding atmosphere (air).

The communication equipment 150 may include the TIM 183. The TIM 183 may transfer heat generated from devices (e.g., optical module assembly 185, RF components, chips) to the heatsink 181.

The communication equipment 150 may include an optical module assembly 185. The optical module assembly 185 refers to a structure in which an optical module and a cage for fixing of the optical module are coupled. The optical module refers to an optical transceiver. The optical module assembly 185 may include the cage and the optical module. A side (e.g., a top side) of the cage of the optical module assembly 185 is connected to a heat dissipation FIN through the TIM 183, thereby enabling cooling of the optical module. The cage according to an embodiment may be coupled with a metal pad. A side of the cage may be coupled with the metal pad. The cage having a structure coupled to the metal pad may be referred to as a metal pad-type cage, a metal pad-coupled cage, a metal pad-based cage, and a metal pad-equipped cage, or other technical term that is equivalent or similar to thereto. Hereinafter, a metal pad-type cage will be typically described as a reference.

The communication equipment 150 may include a PCB 187. The PCB 187 may include one or more elements for electrical connections. Each element functions as a heat source. Heat generated in the PCB 187 may be transferred to the optical module assembly 185. As the heat generated from the optical module assembly 185 itself is added to the heat transferred from the PCB 187, the temperature may increase. Thus, its improved heat transfer path may be required to address the problem of rising temperatures.

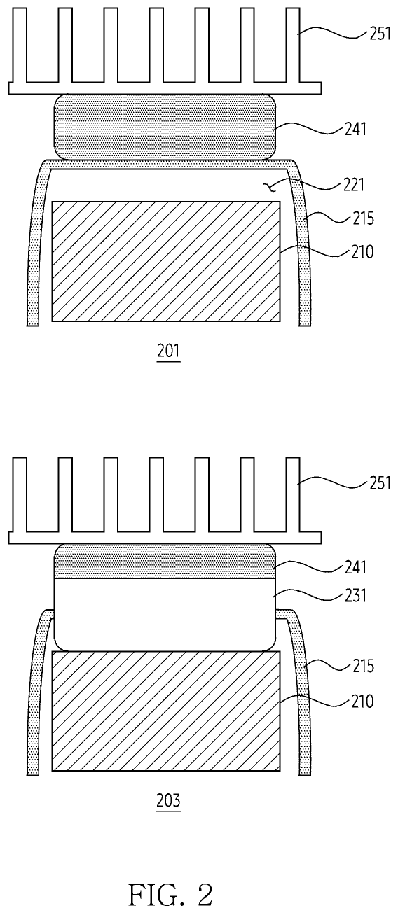

FIG. 2 illustrates an enclosure-type cage according to an embodiment of the disclosure.

Referring to FIG. 2, in a first structure 201, a cage 215 may accommodate an optical module 210 without a heatsink. A thermal pad 241 may be placed on an upper surface of the cage 215. The thermal pad 241 may be in contact with a heat dissipation FIN 251 of the enclosure. Heat of the optical module 210 may be transferred through the cage 215, the thermal pad 241, and the heat dissipation FIN 251. An air gap 221 may exist between the optical module 210 and the cage 215. Due to the air gap 221, thermal resistance increases, and thus the heat dissipation function of the cage 215 may be ineffective.

In a second structure 203, the cage 215 may be connected to a heatsink block 231. The cage 215 may accommodate the optical module 210. Disposing the heatsink block 231 on an upper surface of the cage 215 allows the air gap between the cage 215 and the optical module 210 to be reduced. The heatsink block 231 is connected to the cage 215 through a clip portion, and the heatsink block 231 may be placed on the upper surface of the cage 215 so that the optical module 210 and the cage 215 are in contact. Due to the removal of the air gap, the heat dissipation effect is improved, but there may be a disadvantage due to the heatsink block 231. For example, due to the arrangement of the heatsink block 231, it may not be easy to insert the optical module 210 into the cage 215 and remove it therefrom. Further, for example, additional arrangement of the heatsink block 231 may be disadvantageous in terms of costs.

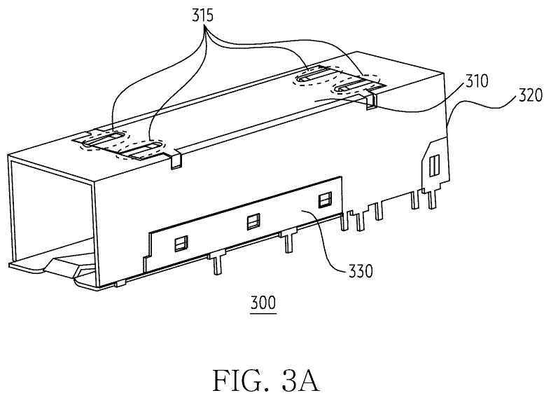

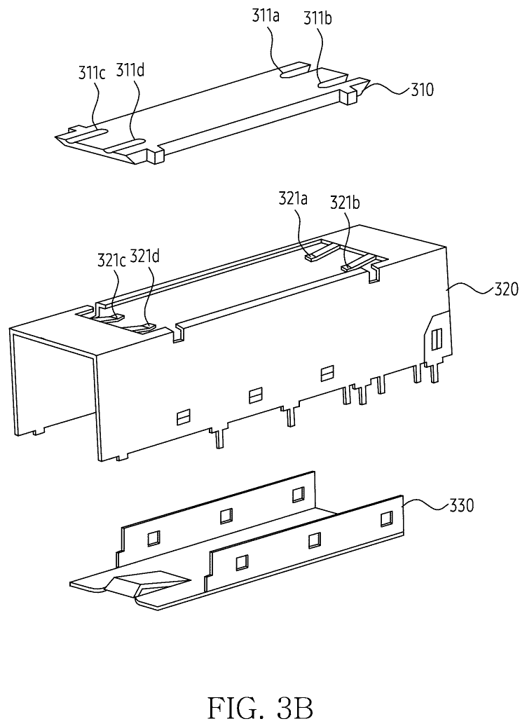

As described above, to address such problems, the disclosure describes a cage coupled with a metal pad (i.e., a metal pad-type cage). By combining the metal pad with the cage instead of heatsinks, heat transfer performance may be improved and the drawbacks of heatsinks may be alleviated or eliminated. Hereinafter, an example of such a metal pad-type cage will be described through FIGS. 3A and 3B.

FIG. 3A illustrates a metal pad-type cage according to an embodiment of the disclosure. FIG. 3B is an exploded perspective view of a metal pad-type cage according to an embodiment of the disclosure.

The metal pad-type cage is a component of communication equipment (e.g., the communication equipment 150 in FIG. 1B) and may be disposed in a certain area (e.g., an area of the optical module assembly 185).

Referring to FIGS. 3A and 3B, a metal pad-type cage 300 may include a metal pad 310, a main body cage 320, and a bottom cage 330. For example, for effective heat transfer, the metal pad 310 may be made of aluminum (Al). Further, for example, for effective heat transfer, the main body cage 320 and the bottom cage 330 may each be made of copper (Cu) alloy. As an example, the copper alloy may include a copper-nickel-zinc alloy.

The metal pad-type cage 300 may include the metal pad 310. The metal pad 310 may be placed on one side of the main body cage 320. The main body cage 320 may have a structure for accommodating an optical module (e.g., a small form-factor pluggable (SFP) optical module). The metal pad-type cage 300 according to embodiments may use the metal pad 310 of a certain thickness (e.g., about 0.8 mm (millimeter)) as a heat dissipation component instead of the heatsink block 231 in FIG. 2. Owing to the arrangement of the metal pad 310 in contact with the optical module, the air gap may be reduced (or eliminated). An internal height of the metal pad-type cage 300 may be defined as a length from a bottom surface of the metal pad-type cage 300 to a lowermost surface of the metal pad 310. According to an embodiment of the disclosure, the internal height of the metal pad-type cage 300 (e.g., about 8.15±0.25 mm) may be configured to be less than or equal to the height of the optical module (e.g., about 8.4 to 8.7 mm). When the optical module is inserted, the metal pad 310 is pushed upward, so that the metal pad 310 may be in contact with the optical module. Due to such contact, the air gap may be eliminated. By eliminating the air gap, thermal conductivity between the optical module and the metal pad-type cage 300 may be improved.

According to an embodiment of the disclosure, the metal pad 310 may have a flexible height depending on whether the optical module is mounted thereon. In the metal pad-type cage 300, the height of the metal pad 310 may vary depending on the insertion or extraction of the optical module. In this case, the metal pad-type cage 300 may include a contact structure 315 to prevent an air gap due to movement of the metal pad 310. The metal pad 310 may include structures for the contact structure 315 (e.g., groove 311a, groove 311b, groove 311c, and groove 311d). The main body cage 320 may include a structure for the contact structure 315 (e.g., leaf spring 321a, leaf spring 321b, leaf spring 321c, and leaf spring 321d). For example, the metal pad 310 may accommodate the leaf spring 321a through the groove 311a. The groove 311a may be an opening formed in a portion of the height of the metal pad 310.

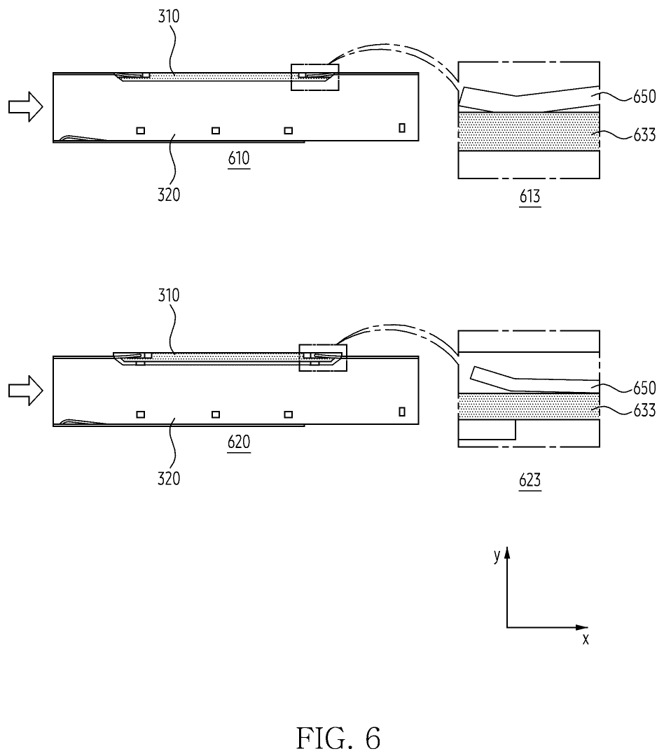

The groove 311a may be formed in the metal pad 310 so as not to restrict the movement of the leaf spring 321a. As the optical module is inserted, the height of the metal pad 310 from a reference surface (e.g., the bottom of the metal pad-type cage 300) may increase. When the optical module is inserted, the height of the bottom forming the groove 311a of the metal pad 310 also increases. The bottom part contacts the leaf spring 321a. Some area of the leaf spring 321a may be arranged to press against the underside of the metal pad 310 as the leaf spring 321a is bent. The description of the contact structure of the groove 311a and the leaf spring 321a may also be similarly equally applied to the contact structure of the groove 311b and the leaf spring 321b, the contact structure of the groove 311c and the leaf spring 321c, and the groove 311d and the leaf spring 321d. The same can be applied to the contact structure of the leaf spring 321d. For understanding structural principles for the contact structure 315, reference may be made to FIG. 6.

While four contact structures are illustrated in FIGS. 3A and 3B, embodiments of the disclosure are not limited thereto. The four contact structures are only of examples and more than four contact structures may be formed on the metal pad-type cage, or less than four contact structure(s) may be formed on the metal pad-type cage.

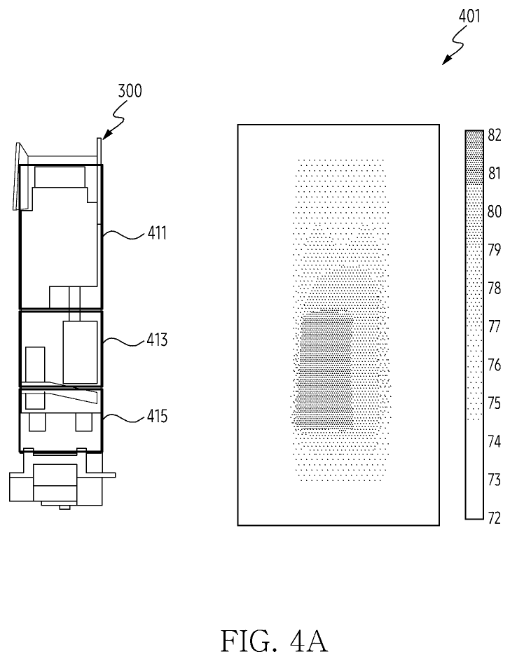

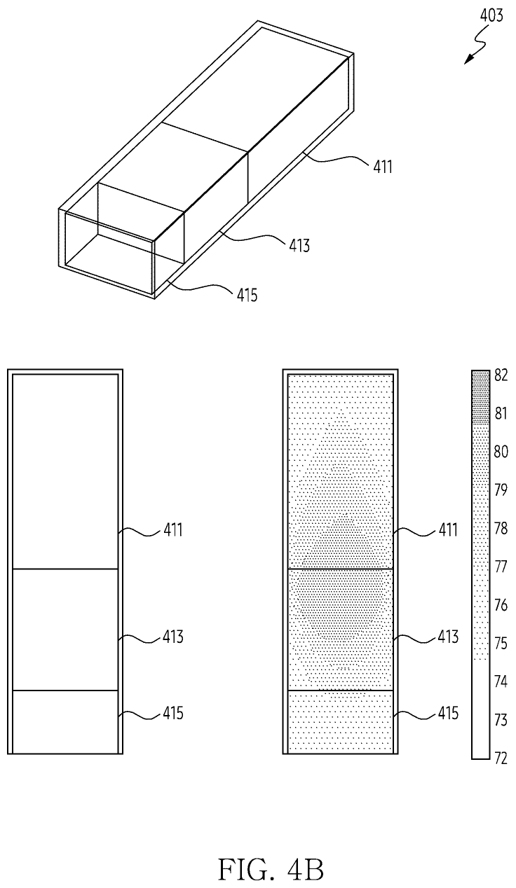

FIGS. 4A and 4B illustrate a performance of a metal pad-type cage according to various embodiments of the disclosure. FIG. 4A illustrates an experimental result of a cage in which an actual optical module is disposed, and FIG. 4B illustrates a schematic diagram of the experimental result.

Referring to FIGS. 4A and 4B, the optical module may be inserted into the metal pad-type cage (e.g., metal pad-type cage 300). The metal pad-type cage 300 including the optical module may include a first heating element (e.g., RF chip) in a first area 411. The metal pad-type cage 300 including the optical module may include a second heating element (e.g., transceiver) in a second area 413. The metal pad-type cage 300 including the optical module may include a connector for electrical connection in a third area 415. A graph 401 may be referred to for heat generation of the metal pad-type cage 300 in which the optical module is accommodated. A graph 403 may be referred to for heat generation for each area of the metal pad-type cage 300.

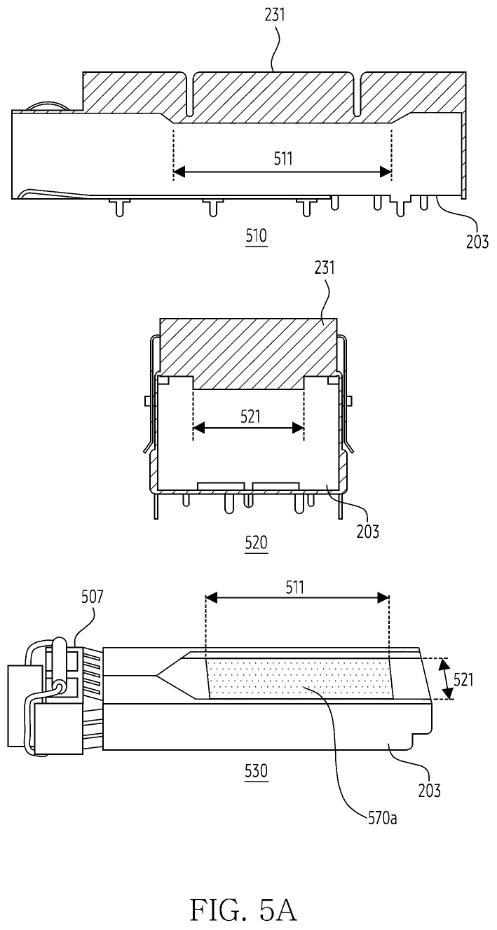

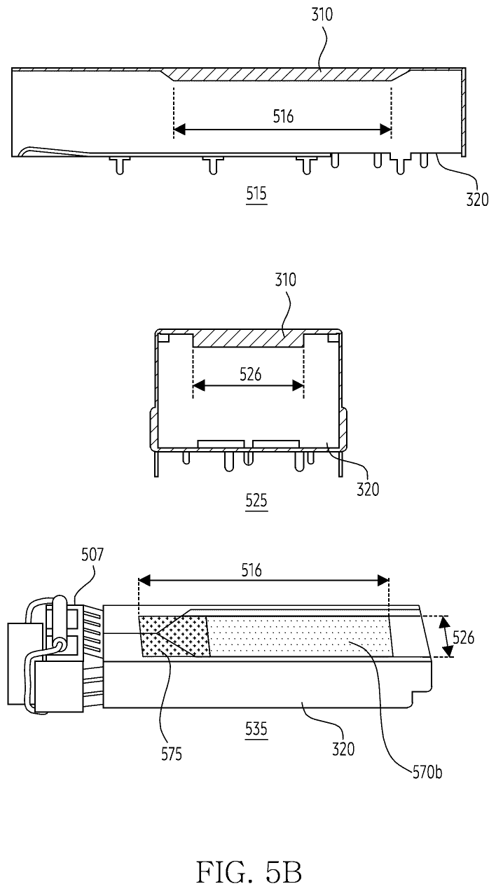

FIGS. 5A and 5B illustrate placement of an optical module and a heat dissipation component according to various embodiments of the disclosure.

As a heatsink component, the heatsink block 231 of FIG. 2 or the metal pad 310 of FIGS. 3A and 3B may be exemplified. FIG. 5A illustrates a contact area of a cage according to a second structure of FIG. 2, and FIG. 5B illustrates a contact area of a metal pad-type cage of FIG. 3A. Here, the contact area refers to an area where the optical module inserted into the cage comes into contact with the heat dissipation component (e.g., heatsink or metal pad) on an upper surface of the cage.

Referring to FIG. 5A, a heatsink block 231 may be disposed on a side (e.g., top surface) of the cage 215 according to the second structure 203. A contact area 570a refers to an area where the optical module 507 inserted into the cage 215 comes into contact with the heatsink block 231. To prevent the heatsink block 231 from leaving the upper surface of the cage 215, the heatsink block 231 may include a clip structure. Due to the clip structure, the contact area 570a may be formed in a limited manner. Referring to the side cross-sectional view 510, a length 511 (e.g., about 23 mm) of the contact area 570a may be determined based on the arrangement of the heatsink block 231. Referring to the front cross-sectional view 520, a width 521 (e.g., about 8.5 mm) of the contact area 570a may be determined based on the arrangement of the heatsink block 231. Referring to a perspective view 530, the contact area 570a may be specified by the length 511 and the width 521.

Referring to FIG. 5B, the metal pad 310 may be disposed on one side (e.g., top surface) of the metal pad-type cage 300. A contact area 570b refers to an area where the optical module 507 inserted into the metal pad-type cage 300 contacts the metal pad 310. Instead of a separate structure for fixing the heatsink block 231, with such a leaf spring structure, the area of the contact area 570b of the metal pad-type cage 300 compared to the contact area 570a of the cage of the second structure 203 may increase. Referring to a side cross-sectional view 515, a length 516 (e.g., about 31 mm) of the contact area 570b may be determined based on the arrangement of the metal pad 310. Referring to a front cross-sectional view 525, a width 526 (e.g., about 12 mm) of the contact area 570b may be determined based on the arrangement of the metal pad 310. Referring to a perspective view 535, the contact area 570b may be specified by the length 516 and width 526.

As the heatsink block 231 of FIG. 5A is removed, the contact area between the metal pad 310 of the metal pad-type cage 300 of FIG. 5B and the optical module may increase. Such an increased area of the contact area (e.g., area 575) allows the metal pad 310 to provide contact to various heating portions of the optical module. For example, as the contact area of the metal pad-like cage 300 increases, additional contact areas for components of the optical module (e.g., laser diode area) may be obtained in an area of the metal pad 310.

FIG. 6 illustrates a contact structure of a metal pad-type cage according to an embodiment of the disclosure.

Referring to FIG. 6, a first state 610 refers to a state of the metal pad-type cage 300 before the optical module is inserted. A second state 620 refers to a state of the metal pad-type cage 300 after the optical module is inserted. The metal pad-type cage 300 may include the main body cage (e.g., the main body cage 300) and the metal pad 310. The main body cage 320 may include a structure 633 for a contact structure 613 or 623. According to an embodiment of the disclosure, the main body cage 320 may include a leaf spring 650. The leaf spring 650 may have a bent plate shape. The metal pad 310 may include a structure 633 for the contact structure 613 or 623. According to an embodiment of the disclosure, the metal pad 310 may include an open structure to accommodate the leaf spring 650 (e.g., groove 311a, groove 311b, groove 311c, groove 311d). The open structure is open in +y-axis direction, and one side of the metal pad 310 may be located in-y-axis direction. For example, the open structure may be formed at a portion of the height of the metal pad 310. At least some area of the leaf spring 750 may come into contact with the one side of the open structure.

As the optical module is inserted, the top surface of the optical module may come into contact with the metal pad 310. As the optical module is inserted, the height of the metal pad 310 increases compared to the reference surface (e.g., the lower surface of the metal pad-type cage 300). As the height of the metal pad 310 increases, the arrangement of the leaf spring 650 may change. When the optical module is assembled (or inserted) into the metal pad-type cage 300, the metal pad 310 in contact with the upper surface of the optical module is pushed upward and rises. At this time, the leaf spring 650 disposed integrally with the main body cage 320 of the metal pad-type cage 300 may press the metal pad 310 downward. As the leaf spring 650 presses the metal pad 310 downward, the metal pad 310 may contact the optical module. As the metal pad 310 contacts the optical module, an air gap between the metal pad 310 and the optical module may be eliminated. According to an embodiment of the disclosure, a terminal area of the leaf spring 650 may be designed not to exceed the upper surface of the metal pad 310.

According to an embodiment of the disclosure, the metal pad 310 of the metal pad-type cage 300 may transfer heat to the heat dissipation structure of the enclosure (e.g., the heatsink 181 of the main body) by directly contacting the optical module. In a state of the optical module being not inserted (e.g., the first state 610), the metal pad 310 may be disposed such that the height of the metal pad 310 from a reference surface (e.g., the underside of the metal pad-type cage 300) does not exceed the upper surface thereof. As the optical module is inserted, the metal pad 310 may move. The metal pad 310 may contact the optical module. In a state of the optical module being inserted into the main body cage 320, the main body cage 320 may include the leaf spring 650 so that the metal pad 310 maintains contact with the optical module. The metal pad 310 of the metal pad-type cage 300 may be disposed as a heatsink so as to contact an area of the optical module including a main heat-generating component of the optical module (e.g., a laser diode).

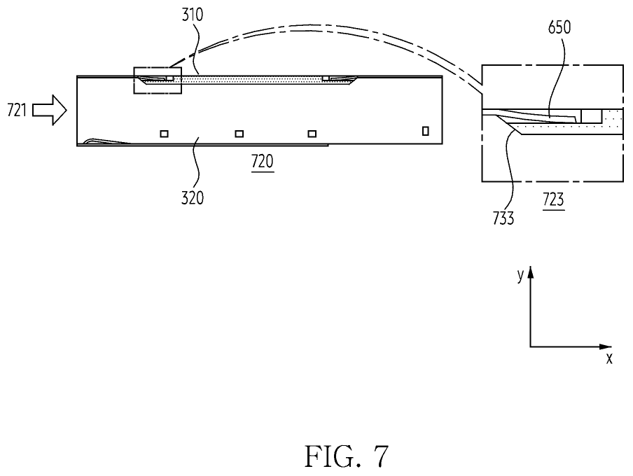

FIG. 7 illustrates a coupling part of a metal pad-type cage according to an embodiment of the disclosure. The coupling part refers to a coupling area between the optical module and the main body cage of the metal pad-type cage 300.

Referring to FIG. 7, the metal pad-type cage 300 may include the metal pad 310 and the main body cage 320. The optical module may be inserted into the main body cage 320 in +x-axis direction 721. When the optical module is inserted into the main body cage 320, the height of the metal pad 310 may increase. For easy insertion of the optical module, the metal pad 310 may include a structure 733 for an oblique structure 723. When the optical module is inserted into the main body cage 320, the oblique structure 723 may be formed in at least one end area of the metal pad 310 to reduce resistance with the metal pad 310. An area of a first surface (e.g., top surface) of the metal pad 310 may be greater than that of a second surface (e.g., bottom surface) of the metal pad 310. A side of the metal pad 310 disposed between the first and second surfaces of the metal pad 310 may be formed in a direction inclined with respect to a direction perpendicular to the first and second surfaces. The metal pad 310 may have its lateral surface formed obliquely from top to bottom (−y-axis direction).

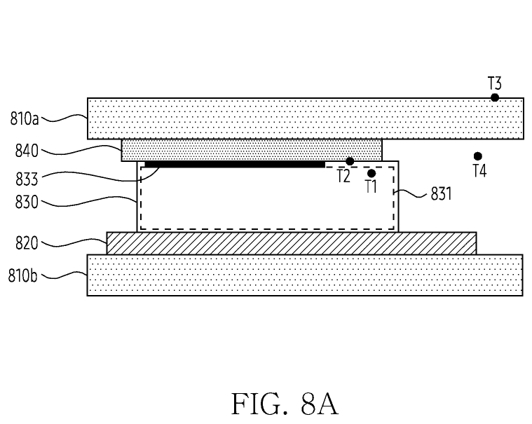

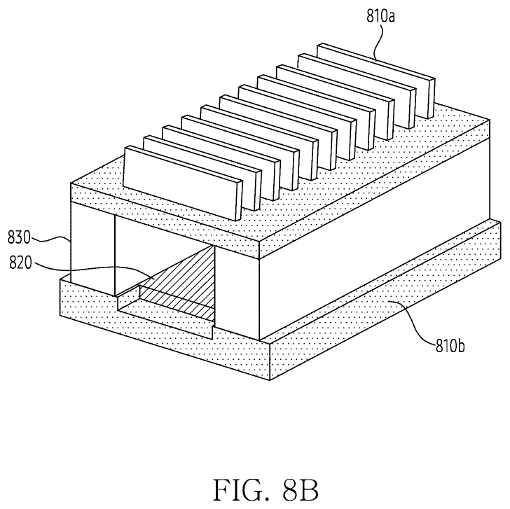

FIGS. 8A and 8B illustrate a stacked structure of a metal pad-type cage according to various embodiments of the disclosure. For testing the heat dissipation performance, communication equipment may be coupled with a test jig. The communication equipment to be tested may include a metal pad-type cage 300.

Referring to FIG. 8A, illustrated is a cross-section of a heat dissipation structure including the metal pad-type cage 300 disposed in a test jig. Referring to FIG. 8B, illustrated is a perspective view of the heat dissipation structure including the metal pad-type cage 300 disposed in the test jig.

The test jig may include a first jig housing 810a and a second jig housing 810b. A PCB 820 may be disposed on the second jig housing 810b. A metal pad-type cage 830 may be disposed on the PCB 820. The metal pad-type cage 830 illustrates an example of the metal pad-type cage 300. The metal pad-type cage 830 may include an optical module 831. The metal pad-type cage 830 may include a metal pad 833. For the arrangement structure of the metal pad 833, the description of the metal pad 310 described in FIGS. 3A, 3B, 4A, 4B, 5A, 5B, 6, and 7 may be applied. A TIM 840 may be disposed on one side of the metal pad-type cage 830. The first jig housing 810a may be disposed on the TIM 840.

The first test point T1 is a temperature measurement point for the heating element. The second test point T2 is a temperature measurement point for the cage, that is, the heatsink. The third test point T3 is a heat dissipation measurement point. The fourth test point T4 is a temperature measurement point for the outside. Heat dissipation characteristics may be measured based on a difference between the temperature at the first test point T1 and the temperature at the fourth test point T4. Further, since the metal pad-type cage 300 according to embodiments of the disclosure does not require a separate heatsink block, the overall costs of the heat dissipation structure may be reduced. Furthermore, the inserting or removing force of the optical module may be improved by coupling of the leaf spring structure of the cage and the groove of the metal pad.

Due to improved heat dissipation characteristics, the length of the product's heat sink fins may be reduced in the enclosure of communications equipment. Such improved thermal characteristics may allow for closer placement of optical modules and other heating elements (e.g., communication chips). As the communication area decreases, it may be possible to implement the communication equipment on lower-spec PCBs. The low-spec PCBs allow for improved system design.

In embodiments of the disclosure, an optical cage is provided. The optical cage may include a first cage for accommodating an optical module, a second cage for supporting the optical module, and a metal pad. A side of the metal pad may be coupled to a side of the optical module. A plurality of grooves may be formed on the side of the metal pad. An opening may be formed on the side of the first cage. A plurality of plate spring structures integrally formed with the first cage may be disposed within the opening. The plurality of plate spring structures may be coupled to a corresponding groove among the plurality of grooves. The metal pad may be movably disposed by insertion of the optical module into the first cage or withdrawal of the optical module from the first cage.

According to an embodiment of the disclosure, the plurality of grooves may include a first groove and a second groove. The plurality of plate spring structures may include a first plate spring structure and a second plate spring structure. In a case where the optical module is inserted into the first cage, the first plate spring structure may contact a first region of the metal pad where the first groove is formed, and the second plate spring structure may contact a second region of the metal pad where the second groove is formed.

According to an embodiment of the disclosure, the first plate spring structure may have a curved plate shape, and a portion of the curved plate shape of the first plate spring structure may contact the first region of the metal pad. The second plate spring structure may have a curved plate shape, and a portion of the curved plate shape of the second plate spring structure may contact the second region of the metal pad.

According to an embodiment of the disclosure, the plurality of grooves may include a third groove and a fourth groove. The plurality of plate spring structures may include a third plate spring structure and a fourth plate spring structure. In a case where the optical module is inserted into the first cage, the third plate spring structure may contact a third region of the metal pad where the third groove is formed and the fourth plate spring structure may contact a fourth region of the metal pad where the fourth groove is formed.

According to an embodiment of the disclosure, a height of the metal pad in case of the optical module being inserted into the first cage may be higher than a height of the metal pad in case of the optical module being withdrawn from the first cage or not being inserted into the first cage.

According to an embodiment of the disclosure, an area of the side of the metal pad may be larger than an area of a side opposite the side of the metal pad. A lateral side of the metal pad may be formed in a direction inclined relative to a direction perpendicular to the area of the side.

According to an embodiment of the disclosure, the metal pad may be made of aluminum. Each of the first cage and the second cage may be made of a copper-nickel-zinc alloy.

According to an embodiment of the disclosure, in a state where the optical module is not inserted into the first cage, the metal pad may be disposed such that a height from a bottom side of the second cage to the metal pad is lower than a height of the optical module.

According to an embodiment of the disclosure, in a state where the optical module is not inserted into the first cage, the metal pad may be disposed such that an opposite side of the side of the metal pad is located below the side of the first cage.

According to an embodiment of the disclosure, in a case where the optical module is inserted into the first cage, at least a portion of the metal pad may contact a region of the optical module.

In embodiments of the disclosure, communication equipment is provided. The communication equipment may include a heat dissipation fin, a thermal interface material (TIM), an optical module, an optical cage, and a printed circuit board (PCB). The optical cage may be disposed on a side of the PCB. The optical cage may include a first cage for accommodating the optical module, a second cage for supporting the optical module, and a metal pad. A side of the metal pad may be coupled to a side of the optical module. A plurality of grooves may be formed on the side of the metal pad. An opening may be formed on the side of the first cage. A plurality of plate spring structures integrally formed with the first cage may be disposed within the opening. The plurality of plate spring structures may be coupled to a corresponding groove among the plurality of grooves. The metal pad may be movably arranged by insertion of the optical module into the first cage or withdrawal of the optical module from the first cage.

According to an embodiment of the disclosure, the plurality of grooves may include a first groove and a second groove. The plurality of plate spring structures may include a first plate spring structure and a second plate spring structure. In a case where the optical module is inserted into the first cage, the first plate spring structure may contact a first region of the metal pad where the first groove is formed, and the second plate spring structure may contact a second region of the metal pad where the second groove is formed.

According to an embodiment of the disclosure, the first plate spring structure may have a curved plate shape, and a portion of the curved plate shape of the first plate spring structure may contact the first region of the metal pad. The second plate spring structure may have a curved plate shape, and a portion of the curved plate shape of the second plate spring structure may contact the second region of the metal pad.

According to an embodiment of the disclosure, the plurality of grooves may include a third groove and a fourth groove. The plurality of plate spring structures include a third plate spring structure and a fourth plate spring structure. In a case where the optical module is inserted into the first cage, the third plate spring structure may contact a third region of the metal pad where the third groove is formed, and the fourth plate spring structure may contact a fourth region of the metal pad where the fourth groove is formed.

According to an embodiment of the disclosure, a height of the metal pad in case of the optical module being inserted into the first cage may be greater than a height of the metal pad in case of the optical module being withdrawn from the first cage or not being inserted into the first cage.

According to an embodiment of the disclosure, an area of the side of the metal pad may be larger than an area of a side opposite to the side of the metal pad. A lateral side of the metal pad may be formed in a direction inclined relative to a direction perpendicular to the area of the side.

According to an embodiment of the disclosure, the metal pad may be made of aluminum. Each of the first cage and the second cage may be made of a copper-nickel-zinc alloy.

According to an embodiment of the disclosure, in a state where the optical module is not inserted into the first cage, the metal pad may be disposed such that a height from a bottom side of the second cage to the metal pad is lower than a height of the optical module.

According to an embodiment of the disclosure, in a state where the optical module is not inserted into the first cage, the metal pad may be disposed such that an opposite side of the side of the metal pad is located below the side of the first cage.

According to an embodiment of the disclosure, in a case where the optical module is inserted into the first cage, at least a portion of the metal pad may contact a region of the optical module.

An optical cage and communication equipment including the same according to embodiments of the disclosure can improve the heat dissipation performance and increase the space efficiency by providing contact between a metal pad and an optical module through the metal pad that is coupled to one side of the cage and has a flexible arrangement.

The effects that can be obtained from the disclosure are not limited to those mentioned above, and other effects not mentioned herein may be clearly understood by those skilled in the art from the foregoing description.

An array antenna according to embodiments of the disclosure may include a deformable structure in a dielectric substrate around a power divider. A decoupling coupler may be disposed to transfer power between a power divider capable of antenna feeding and a radiator that radiates energy. The decoupling coupler according to embodiments may function as a decoupling matching network. To improve isolation between two signals of different polarizations, the decoupling coupler may provide an electrical connection between the two power dividers. As the decoupling coupler is disposed, the isolation performance can be secured without additional space, such as a wall. Further, by placing the power divider behind the antenna substrate, the space between the antenna substrate and the antenna element can be secured to facilitate better design. Furthermore, the decoupling coupler has the advantage of less gain loss and easier implementation than a defected ground method.

The methods according to various embodiments described in the claims and/or specification of the disclosure may be implemented in hardware, software, or a combination of hardware and software.

In case of implementation as software, a computer-readable storage medium for storing one or more programs (software modules) may be provided. The one or more programs stored in the computer-readable storage medium are configured for execution by one or more processors in an electronic device. The one or more programs include instructions that cause the electronic device to execute the methods according to embodiments described in the claims or specifications of the disclosure.

Such a program (software module, software) may be stored in random access memory, non-volatile memory including flash memory, read only memory (ROM), electrically erasable programmable read only memory (EEPROM), magnetic disc storage device, compact disc-ROM (CD-ROM), digital versatile discs (DVDs), other type of optical storage device, or a magnetic cassette. Alternatively, the program may be stored in memory including a combination of some or all of those. In addition, a plurality of respective constituent memories may be included therein.

Further, the program may be stored in an attachable storage device that may be accessed through a communication network, such as e.g., Internet, Intranet, local area network (LAN), wide area network (WAN), or storage area network (SAN), or a combination thereof. Such a storage device may be connected to a device performing an embodiment of the disclosure via an external port. Further, a separate storage device on the communication network may also access a device performing an embodiment of the disclosure.

In the above-described specific embodiments of the disclosure, an element included in the disclosure is expressed in a singular or plural form depending on a presented specific embodiment. However, the singular form or plural form is selected to better suit its presented situation for the convenience of description, and the disclosure is not limited to that singular element or the plural element presented, and even a component expressed in plural may be configured in a singular form, or even a component expressed in a singular form may be configured in a plural form.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An optical cage comprising:
a first cage for accommodating an optical module;
a second cage for supporting the optical module; and
a metal pad,
wherein a side of the metal pad is coupled to a side of the optical module,
wherein a plurality of grooves is formed on the side of the metal pad,
wherein an opening is formed on the side of the first cage,
wherein a plurality of plate spring structures integrally formed with the first cage is disposed within the opening,
wherein the plurality of plate spring structures is coupled to a corresponding groove among the plurality of grooves, and
wherein the metal pad is movably disposed by insertion of the optical module into the first cage or withdrawal of the optical module from the first cage.

2. The optical cage of claim 1,
wherein the plurality of grooves include a first groove and a second groove,
wherein the plurality of plate spring structures include a first plate spring structure and a second plate spring structure, and
wherein, in a case that the optical module is inserted into the first cage, the first plate spring structure contacts a first region of the metal pad where the first groove is formed and the second plate spring structure contacts a second region of the metal pad where the second groove is formed.

3. The optical cage of claim 2,
wherein the first plate spring structure has a curved plate shape, and a portion of the curved plate shape of the first plate spring structure contacts the first region of the metal pad, and
wherein the second plate spring structure has a curved plate shape, and a portion of the curved plate shape of the second plate spring structure contacts the second region of the metal pad.

4. The optical cage of claim 2,
wherein the plurality of grooves include a third groove and a fourth groove,
wherein the plurality of plate spring structures include a third plate spring structure and a fourth plate spring structure, and
wherein, in a case that the optical module is inserted into the first cage, the third plate spring structure contacts a third region of the metal pad where the third groove is formed and the fourth plate spring structure contacts a fourth region of the metal pad where the fourth groove is formed.

5. The optical cage of claim 1, wherein a height of the metal pad in case of the optical module being inserted into the first cage is higher than a height of the metal pad in case of the optical module being withdrawn from the first cage or not being inserted into the first cage.

6. The optical cage of claim 1,
wherein an area of the side of the metal pad is larger than an area of a side opposite the side of the metal pad, and
wherein a lateral side of the metal pad is formed in a direction inclined relative to a direction perpendicular to the area of the side.

7. The optical cage of claim 1,
wherein the metal pad is made of aluminum, and
wherein each of the first cage and the second cage is made of a copper-nickel-zinc alloy.

8. The optical cage of claim 1, wherein, in a state where the optical module is not inserted into the first cage, the metal pad is disposed such that a height from a bottom side of the second cage to the metal pad is lower than a height of the optical module.

9. The optical cage of claim 1, wherein, in a state where the optical module is not inserted into the first cage, the metal pad is disposed such that an opposite side of the side of the metal pad is located below the side of the first cage.

10. The optical cage of claim 1, wherein, in a case that the optical module is inserted into the first cage, at least a portion of the metal pad contacts a region of the optical module.

11. A communication equipment comprising:
a heat dissipation fin;
a thermal interface material (TIM);
an optical module;
an optical cage; and
a printed circuit board (PCB),
wherein the optical cage is disposed on a side of the PCB,
wherein the optical cage includes:
a first cage for accommodating the optical module,
a second cage for supporting the optical module, and
a metal pad,
wherein a side of the metal pad is coupled to a side of the optical module,
wherein a plurality of grooves is formed on the side of the metal pad,
wherein an opening is formed on the side of the first cage,
wherein a plurality of plate spring structures integrally formed with the first cage is disposed within the opening,
wherein the plurality of plate spring structures is coupled to a corresponding groove among the plurality of grooves, and
wherein the metal pad is movably arranged by insertion of the optical module into the first cage or withdrawal of the optical module from the first cage.

12. The communication equipment of claim 11,
wherein the plurality of grooves include a first groove and a second groove,
wherein the plurality of plate spring structures include a first plate spring structure and a second plate spring structure, and
wherein, in a case that the optical module is inserted into the first cage, the first plate spring structure contacts a first region of the metal pad where the first groove is formed and the second plate spring structure contacts a second region of the metal pad where the second groove is formed.

13. The communication equipment of claim 12,
wherein the first plate spring structure has a curved plate shape and a portion of the curved plate shape of the first plate spring structure contacts the first region of the metal pad, and
wherein the second plate spring structure has a curved plate shape and a portion of the curved plate shape of the second plate spring structure contacts the second region of the metal pad.

14. The communication equipment of claim 12,
wherein the plurality of grooves include a third groove and a fourth groove,
wherein the plurality of plate spring structures include a third plate spring structure and a fourth plate spring structure, and
wherein, in a case that the optical module is inserted into the first cage, the third plate spring structure contacts a third region of the metal pad where the third groove is formed and the fourth plate spring structure contacts a fourth region of the metal pad where the fourth groove is formed.

15. The communication equipment of claim 11, wherein a height of the metal pad in case of the optical module being inserted into the first cage is higher than a height of the metal pad in case of the optical module being withdrawn from the first cage or not being inserted into the first cage.

16. The communication equipment of claim 11,
wherein an area of the side of the metal pad is larger than an area of a side opposite the side of the metal pad, and
wherein a lateral side of the metal pad is formed in a direction inclined relative to a direction perpendicular to the area of the side.

17. The communication equipment of claim 11,
wherein the metal pad is made of aluminum, and
wherein each of the first cage and the second cage is made of a copper-nickel-zinc alloy.

18. The communication equipment of claim 11, wherein, in a state where the optical module is not inserted into the first cage, the metal pad is disposed such that a height from a bottom side of the second cage to the metal pad is lower than a height of the optical module.

19. The communication equipment of claim 11, wherein, in a state where the optical module is not inserted into the first cage, the metal pad is disposed such that an opposite side of the side of the metal pad is located below the side of the first cage.

20. The communication equipment of claim 11, wherein, in a case that the optical module is inserted into the first cage, at least a portion of the metal pad contacts a region of the optical module.
